(19) United States
(12) Patent Application Publication
(10) Pub. No.: US 2016/0270232 A1
(43) Pub. Date: Sep. 15, 2016

(54) PRINTED CIRCUIT BOARD AND METHOD OF MANUFACTURING THE SAME

(71) Applicant: SAMSUNG ELECTRO-MECHANICS CO., LTD., Suwon-Si (KR)

(72) Inventors: Jong Rip KIM, Suwon-Si (KR); Jong Myeon LEE, Suwon-Si (KR); Ung Hui SHIN, Suwon-Si (KR); Doo Hwan LEE, Suwon-Si (KR)

(73) Assignee: SAMSUNG ELECTRO-MECHANICS CO., LTD., Suwon-Si (KR)

(21) Appl. No.: 14/871,464

(22) Filed: Sep. 30, 2015

(30) Foreign Application Priority Data
Mar. 11, 2015 (KR) 10-2015-0033786

(51) Int. Cl. H05K 1/18; H05K 3/30; H05K 1/11

(52) U.S. Cl. CPC H05K 1/183; H05K 1/115; H05K 3/306

(57) ABSTRACT

A printed circuit board and a method of manufacturing the same are provided. The printed circuit board includes a core board having a cavity that penetrates through a region of a core layer, an electronic component embedded in the cavity, side surfaces of the cavity contacting the electronic component, and insulating layers disposed on opposite surfaces of the core board.

### CROSS-REFERENCE TO RELATED APPLICATION

This application claims the benefit under 35 USC 119(a) of Korean Patent Application No. 10-2015-0033786 filed on Mar. 11, 2015, in the Korean Intellectual Property Office, the entire disclosure of which is incorporated herein by reference for all purposes.

### BACKGROUND

1. Field

The present disclosure relates to a printed circuit board and a method of manufacturing the same.

2. Description of Related Art

In general, warpage may occur in a printed circuit board (PCB) due to differences in the physical properties of materials stacked thereon such as, for example, due to mismatches between coefficients of thermal expansion (CTE). The warpage of the PCB as described above is a significant factor having a large influence on the PCB and a package process. Consequently, the degree of warpage has an important influence on package yield. Further, in a case of a recent embedded PCB in which an electronic component is embedded, a warpage may occur due to differences in physical properties between the electronic component and the PCB. Particularly, as a size of the electronic component to be embedded increases (or as a ratio of electronic component/printed circuit board increases), warpage tends to increase.

An object of embedding electronic components is to implement a greater number of functions in the same area. As a size of an embedded component is increased, that is, when the embedded component corresponds to a high-value integrated circuit (IC), an effect of the surrounding environment may be decreased and performance of an electronic component may be significantly increased by embedding the component. Therefore, it is important to secure a yield with respect to the embedded component and multiple functions by additionally applying surface-mount technology (SMT).

At the time of embedding the electronic component, a warpage problem caused by differences in mechanical properties between the component and an interior material should be technically solved for mass-production of a component-embedded board. Particularly, in a case of an active element of which an area ratio of an embedded component in a package is large, a technology of decreasing warpage may play a critical role in adopting a technology of embedding a component in the corresponding package.

Currently, in order to embed the electronic component, a method for sequentially stacking prepreg (PPG) on upper and lower portions of copper clad laminate (CCL) has been used. In this case, there are differences in degrees of curing, curing shrinkage, and the like, between the upper and lower PPG on the CCL, which may cause warpage.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a printed circuit board including a core board having a cavity that penetrates through a region of a core layer, an electronic component embedded in the cavity, side surfaces of the cavity contacting the electronic component, and insulating layers disposed on opposite surfaces of the core board.

The insulating layers on opposite surfaces of the core board may have degrees of curing and curing shrinkages that are substantially equal to each other.

The core board may further include inner layer circuit patterns contacting at least one of upper and lower surfaces of the core layer.

A lower surface of the electronic component may be positioned on the same plane as lower surfaces of the inner layer circuit patterns formed on the lower surface of the core layer.

The core board may further include a first via formed in the core layer and electrically connecting the inner layer circuit patterns formed on the upper and lower surfaces of the core layer to each other.

The general aspect of the printed circuit board may further include outer layer circuit patterns formed on at least one surface of the insulating layer, and second and third vias provided in the insulating layer and electrically connecting the outer layer circuit patterns to the inner layer circuit patterns or the electronic component, respectively.

The general aspect of the printed circuit board may further include a contact pad interposed between the electronic component and the third via in the insulating layer.

In another general aspect, a method of manufacturing a printed circuit board involves forming a cavity to penetrate through a region of a core layer of a core board such that the cavity has a size equal to or smaller than a size of an electronic component to be embedded in the cavity, expanding the cavity by a first external stimulus to a size larger than a size of the electronic component, embedding the electronic component in the expanded cavity, contracting the cavity in which the electronic component is embedded by a second external stimulus such that side surfaces of the cavity contact the electronic component, and forming insulating layers on opposite surfaces of the core board embedded with the electronic component.

At least one of the first and second external stimuli may be a temperature.

The second external stimulus may have a temperature lower than a temperature of the first external stimulus.

The first external stimulus may be heating, and the second external stimulus may be cooling.

At time of contracting the cavity of the core board embedded with the electronic component, the electronic component may be inserted into the cavity.

Other features and aspects will be apparent from the following detailed description, the drawings, and the claims.

### BRIEF DESCRIPTION OF THE DRAWINGS

FIG. 1 is a schematic plan view illustrating main features of an example of a printed circuit board according to the present disclosure.

FIG. 2 is a cross-sectional view taken along line I-I′ of the example illustrated in FIG. 1.

FIG. 3 is a flow chart illustrating an example of a method of manufacturing a printed circuit board according to the present disclosure.

FIGS. 4A through 8B are process views illustrating the example of the method of manufacturing a printed circuit board of FIG. 3.

FIGS. 4A and 4B are a plan view and a cross-sectional view, respectively, illustrating an example of a core board in which a cavity in which an electronic component will be embedded is formed.

FIGS. 5A and 5B are a plan view and a cross-sectional view, respectively, illustrating the example of the core board in which the cavity formed therein is expanded.

FIGS. 6A and 6B are a plan view and a cross-sectional view, respectively, illustrating the example of the core board of which the electronic component is embedded in the cavity.

FIGS. 7A and 7B are a plan view and a cross-sectional view, respectively, illustrating an example of an electronic component and the cavity of which side surfaces contact each other due to contraction of the cavity.

FIGS. 8A and 8B are a plan view and a cross-sectional view, respectively, illustrating insulating layers simultaneously formed on and below the example of the core board embedded with the electronic component.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

In the drawings, the shapes and dimensions of elements may be exaggerated for clarity, and the same reference numerals will be used throughout to designate the same or like elements.

According to one example, the present disclosure provides a printed circuit board in which warpage of a board may be decreased.

According another example, the present disclosure also provides a method of manufacturing a printed circuit board capable of decreasing warpage of a board.

According to yet another example, the present disclosure provides a technique for decreasing warpage of a board due to a difference in mechanical property values, a difference in coefficients of thermal expansion (CTE) between an electronic component and an interior material, or differences in degrees of curing and curing shrinkage between upper and lower insulating layers sequentially stacked on opposite surfaces of a core board.

According to yet another example, a printed circuit board in which a discontinuous CTE gap is not present between a cavity provided in a core board and an electronic component embedded in the cavity is provided. The printed circuit board may include upper and lower insulating layers formed on opposite surfaces of the core board and having degrees of curing and curing shrinkage equal or similar to each other.

According to yet another example, the present disclosure provides a method of manufacturing a printed circuit board in which an electronic component may be embedded without using a filler having a relatively large CTE between a cavity and the electronic component by expanding and contracting a cavity, and simultaneously forming insulating layers on opposite surfaces of the core board. In this case, the cavity formed in the core board may be expanded and contracted using an external stimulus such as a temperature.

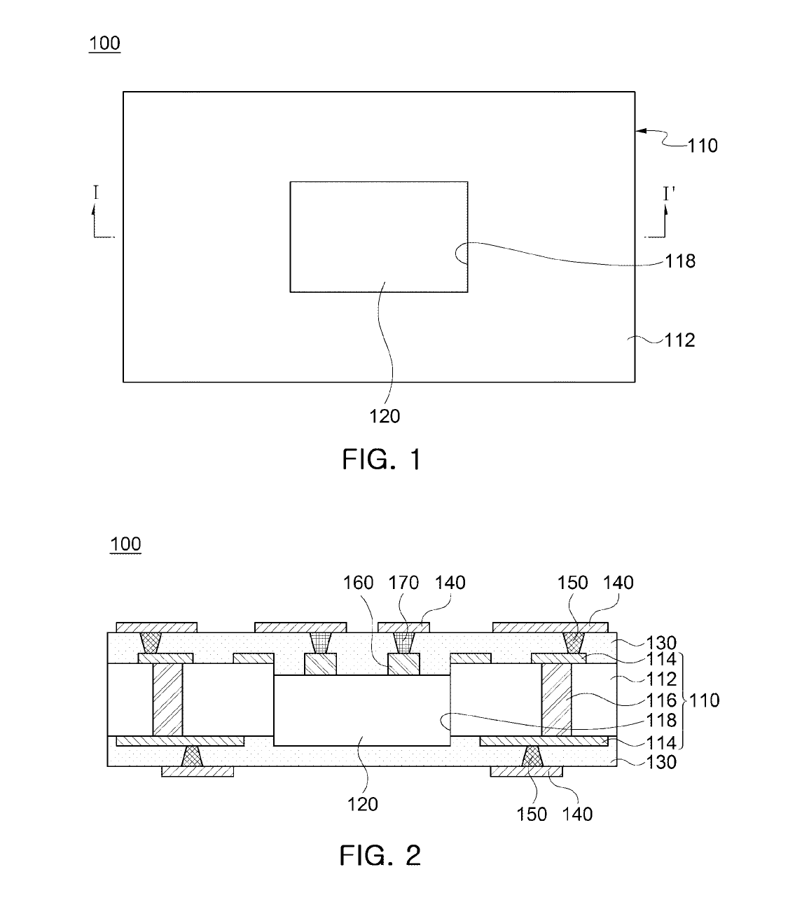

Hereinafter, a printed circuit board according to the present disclosure and a method of manufacturing the same will be described in detail with reference to FIGS. 1 through 8B.

In the present embodiment, horizontal and perpendicular directions of the printed circuit board are defined based on an upper surface of a core layer.

FIG. 1 is a schematic plan view illustrating main features of an example of a printed circuit board according to the present disclosure, and FIG. 2 is a cross-sectional view of the example taken along line I-I′ of FIG. 1.

As illustrated in FIGS. 1 and 2, the printed circuit board 100s include a core board 110 in which a cavity 118 is provided in a core layer 112, an electronic component 120 embedded in the cavity 118, and insulating layers simultaneously formed on opposite surfaces of the core board 110 embedded with the electronic component 120.

Further, the printed circuit board 100 includes inner layer circuit patterns 114, outer layer circuit patterns 140, vias 116, 150, and 170, and a contact pad 160.

The core board 110 includes the core layer 112, the inner layer circuit patterns 114 formed on opposite surfaces, for instance, upper and lower surfaces of the core layer 112, a first via 116 electrically connecting the inner layer circuit patterns 114 formed on upper and lower surfaces of the core layers 112 to each other, and the cavity 118 formed in the core layer 112.

The core layer 112 may serve as a support member while providing a space in which a semiconductor device, for instance, the electronic component 120 is embedded. The core layer 112 may be formed of an insulating material such as prepreg (PPG), or the like, and the insulating material may be impregnated into a core formed of glass cloth or fabric cloth, such that rigidity capable of corresponding to warpage may be imparted.

The inner layer circuit patterns 114 formed on opposite surfaces of the core layer 112 may be used as wiring layers of a multilayer printed circuit board.

The inner layer circuit patterns 114 as described above may be formed of a conductive material, for example, metal foil, a metal layer, or the like. An example of the metal foil may include copper foil, aluminum foil, nickel foil, chromium foil, gold foil, silver foil, and the like. An example of the metal layer may contain copper, aluminum, nickel, chromium, gold, silver, or alloys thereof.

In view of improvement of conductivity and thinness, the inner layer circuit patterns 114 may be formed of copper foil. For example, the core board 110 may be formed of a copper clad laminate (CCL).

The inner layer circuit patterns 114 formed on opposite surfaces of the core layer 112 may be electrically connected to each other by the first via 116 penetrating perpendicularly through the core layer 112 based on the upper surface of the core layer 112.

Meanwhile, although upper and lower inner layer circuit patterns 114 formed on opposite surfaces of the core layer 112 and the first via 116 connecting the upper and lower inner layer circuit patterns 114 to each other are illustrated in FIG. 2, the inner layer circuit patterns 114 and the first via 116 are not necessarily limited thereto. For instance, the inner layer circuit patterns 114 may be formed on either of the upper and lower surfaces of the core layer 112 or may be formed on a surface of another layer instead of the core layer 112, and thus, the first via 116 may also be omitted or a position of the first via 116 may also be changed. For instance, positions, the numbers, shapes, and the like, of the inner layer circuit patterns 114 and the first via 116 may be variously changed depending on a design of the board.

The cavity 118 provided in the core layer 112, which is a space for embedding the electronic component 120, may be formed to perpendicularly penetrate through one region of the core layer 112 based on the upper surface of the core layer 112 in order to miniaturize and thin the printed circuit board.

The electronic component 120 may be embedded in the cavity 118 of the core board 110 without the aid of a separately provided filler to thereby be fixed thereto. In this case, a side surface of the electronic component 120 may contact a side surface of the cavity 118. An interface between the side surfaces of the electronic component 120 and the cavity 118 may become a contact surface.

As illustrated in FIG. 1, a gap layer for the filler does not exist between the side surfaces of the electronic component 120 and the cavity 118. The reason for this is that a size (area) of the electronic component 120 and a size of the cavity 118 are substantially equal to each other. As a result, the electronic component 120 may be in the same state as a state in which the electronic component is interference-fitted into the cavity, which is a state in which the electronic component 120 is structurally engaged with the cavity 118.

In the case of an existing embedded printed circuit board, since a cavity is relatively large, as compared to an electronic component to be embedded therein, an element such as bonding tape is required in order to embed an electronic component in a core cavity, and the electronic component is fixed into the cavity by inserting a filler such as a resin, or the like, into a margin portion of the cavity. In this case, since a discontinuous gap filled with a resin having a large coefficient of thermal expansion (CTE) is generated between the CCL having a small CTE and the electronic component in the horizontal direction of the board, warpage of the board may occur due to mismatch of the CTE between the electronic component and an interior material. Further, in order to fill the margin portion of the cavity with the filler such as the resin, or the like, upper and lower insulating layers of a core board are sequentially stacked, such that warpage of the board may occur due to a difference in curing degree between the upper and lower insulating layers. Here, the sequential stacking may mean that the upper and lower insulating layers are not simultaneously stacked but are sequentially stacked.

However, according to the present example, since an inflection point of a mechanical properties value, for instance, the CTE does not exist between the core board 110 and the electronic component 120 by removing a discontinuous CTE gap in the horizontal direction of the printed circuit board 100 due to a structure in which the filler having a large CTE such as the resin, or the like, does not exist between the cavity 118 of the core board 110 and the electronic component 120 embedded therein, an amount of warpage occurrence of the board may be decreased.

Meanwhile, in a case in which the inner layer circuit pattern 114 is formed on the lower surface of the core layer 112, a lower surface of the electronic component 120 may be positioned on the same plane as a lower surface of the inner layer circuit pattern 114 formed on the lower surface of the core layer 112.

The insulating layers 130 may be simultaneously stacked and formed on opposite surfaces of the electronic component 120 and the core board 110 due to disposition of the electronic component 120 as described above. Here, the simultaneous stacking may mean that the upper and lower insulating layers are stacked simultaneously.

The insulating layers 130 may be formed of the insulating material such as prepreg (PPG), or the like, and the insulating material may be impregnated into the core formed of glass cloth or fabric cloth, such that rigidity capable of corresponding to warpage may be imparted. In this case, as an example of the insulating material, there is a general thermosetting polymer resin suitable for build-up.

The insulating layers 130 simultaneously stacked in the perpendicular direction may have equal or similar degrees of curing and curing shrinkage characteristics to each other on and below the core board 110. Here, the curing shrinkage may mean a shrinkage degree of a cross section during the curing. The term “similar degree” refers to a similarity of approximately 90%. For example, the average shrinkage of a first insulating layer during a temperature change may result in a length difference in one direction. If the length difference of a second insulating layer is within approximately 90%, or within ±10% of the length difference of the first insulating layer, the shrinkage degree of the first and second insulating layers may be described as being similar.

The occurrence amount of warpage of the printed circuit board 100 due to a difference in the curing degree and curing shrinkage in the perpendicular direction may be decreased due to the configuration as described above.

According to the embodiment, the outer layer circuit patterns 140 are formed on the exposed insulating layers 130 while being positioned to have the insulating layers 130 interposed therebetween. The outer layer circuit patterns 140 are provided on an upper surface of the upper insulating layer 130 formed on an upper portion of the core layer 112, and the outer layer circuit patterns 140 are provided on a lower surface of the lower insulating layer 130 formed on a lower portion of the core layer 112. A material of the outer layer circuit patterns 140 as described above may be the same as that of the inner layer circuit patterns 114.

A second via 150 are formed to perpendicularly penetrate through the insulating layers 130 between the inner layer circuit patterns 114 and the outer layer circuit patterns 140, such that the inner layer circuit patterns 114 electrically connect to the outer layer circuit patterns 140 through the second via 150.

Meanwhile, although outer layer circuit patterns 140 stacked on upper and lower portions of the core layer 112 with the insulating layer 130 interposed therebetween, and the second vias 150 are illustrated in FIG. 2, the outer layer circuit patterns 140 and the second vias 150 are not necessarily limited thereto. For instance, the outer layer circuit patterns 140 and the second vias 150 may be variously changed depending on the design of the board. For example, the outer layer circuit patterns 140 may be formed only on one surface of the insulating layer 130, and thus, the second vias 140 may be partially omitted.

Further, referring to FIG. 2, the contact pad 160 is formed on the electronic component 120 in order to improve connectivity with the electronic component 120. A material of the contact pad 160 as described above may be the same as that of the inner layer circuit patterns 114.

A third via 170 is formed to penetrate perpendicularly through the insulating layer 130 between the contact pad 160 and the outer layer circuit pattern 140. Therefore, the contact pad 160 and the outer layer circuit pattern 140 electrically connect to each other through the third via 170, such that the electronic component 120 and the outer layer circuit pattern 140 electrically connect to each other.

Meanwhile, in another example, the contact pad 160 may be omitted in some cases. In this case, the third via 170 may contact the electronic component 120 to electrically connect the electronic component 120 and the outer layer circuit pattern 140 to each other.

In the example of the printed circuit board 100 described above, there is no discontinuous CTE gap in the horizontal direction, and the insulating layers 130 may be simultaneously formed in the perpendicular direction, such that the amount of warpage occurrence due to the difference in the CTE in the horizontal direction and the difference in curing degree and curing shrinkage in the perpendicular direction may be decreased. Therefore, low-warpage may be entirely implemented, such that reliability may be excellent.

The method of manufacturing the printed circuit board according to the present embodiment as described above will be described as follows.

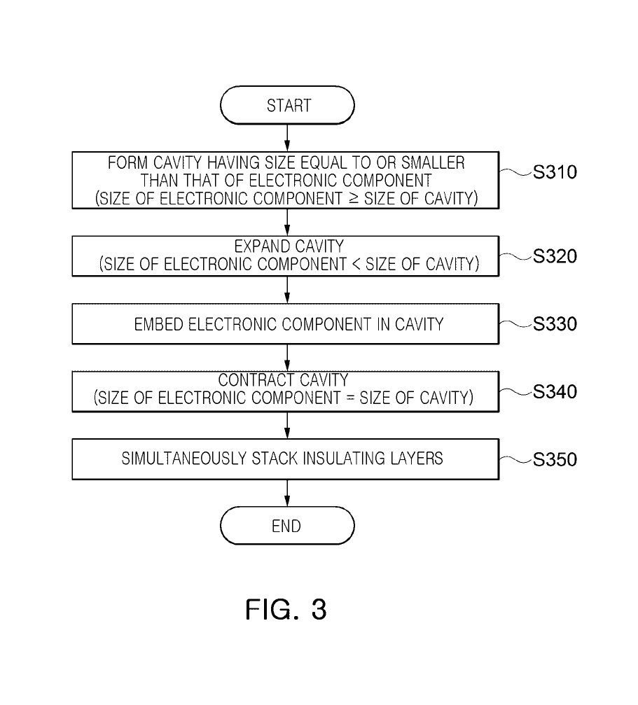

An example of a method of manufacturing a printed circuit board according to FIGS. 1 and 2 will be described with reference to FIG. 3. The same reference numerals will be used with respect to the same components as those in the embodiment illustrated in FIG. 1, and overlapping descriptions of the same components will be omitted such that only differences will be described.

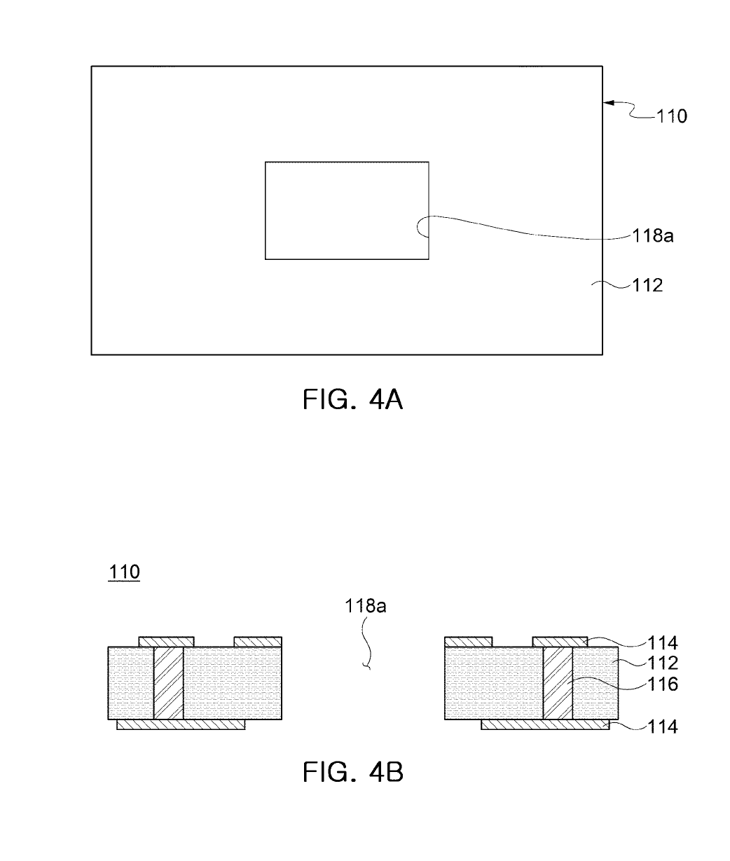

FIG. 3 is a flow chart illustrating an example of a method of manufacturing a printed circuit board according to the present disclosure, and FIGS. 4A through 8B are process views further illustrating the example of the method of manufacturing a printed circuit board according to FIG. 3.

Referring to FIGS. 3 through 4B, in the example of the method of manufacturing a printed circuit board, first, an original cavity 118a having a size (area) equal to or smaller than that of an electronic component to be embedded in a core layer 112 of a core board 110 is formed (S310).

In detail, after preparing a core board 110 such as a CCL, or the like, of which inner layer circuit patterns 114 are provided on opposite surfaces of the core layer 112 and a first via 116 is provided in the core layer 112, the original cavity 118a for in which an electronic component may be embedded is formed to penetrate through one region of the core layer 112.

The original cavity 118a may be formed to have a size equal to or smaller than that of the electronic component to be embedded. An example in which the original cavity 118a is formed to have a size smaller than that of the electronic component to be embedded is illustrated in FIGS. 4A and 4B.

As an example, the original cavity 118a may be formed by processing a region of the core layer in which the electronic component will be embedded using a laser drill such as an yttrium aluminum garnet (YAG) laser drill, CO₂ laser drill, or the like, a mechanical drill, or the like.

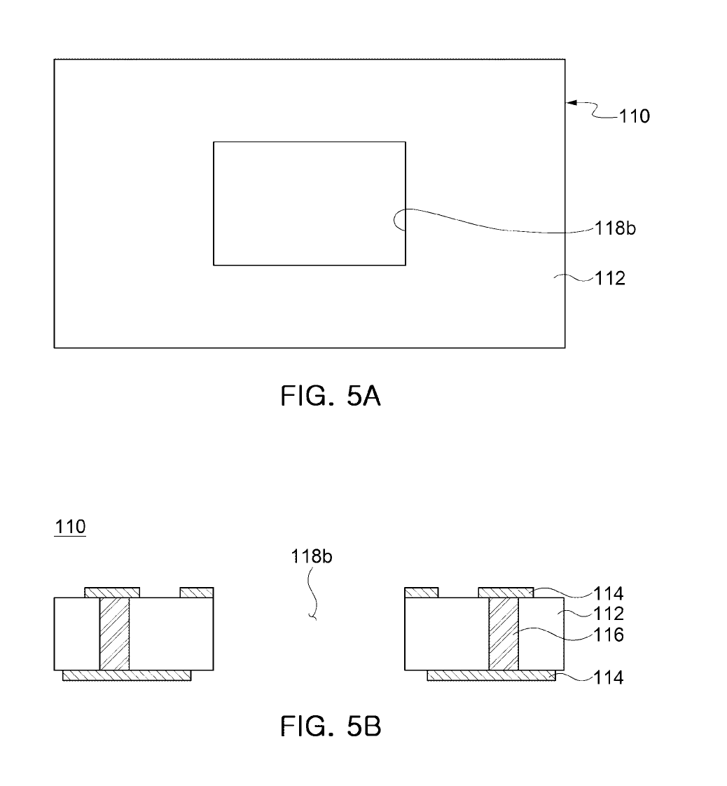

Next, referring to FIGS. 3, 5A, and 5B, the original cavity 118a of FIG. 4A is expanded by a first external stimulus so as to have a size larger than that of the electronic component to be embedded (S320).

In this example, the first external stimulus may be some physical and/or chemical stimulation applied from the outside to the core board 110. The first external stimulus may be, for instance, a temperature-related stimulus.

For example, the first external stimulus may be heating, which is one of methods capable of raising (increasing) a temperature of the core board 110.

As an example, in the expanding of the cavity (S320), the core board 110 including the original cavity 118a of FIG. 4A may be maintained to have a high temperature of at least 100° C., preferably, about 100 to 300° C. for a predetermined time by heating.

In this case, when the temperature of the core board 110 is less than 100° C., an expansion rate of the core layer 112 may be excessively small, such that the cavity may not be sufficiently expanded to have a desired size. On the contrary, when the temperature thereof is more than 300° C., the temperature may be higher than a melting point of the core layer 112, such that it may be difficult to maintain a shape of the core board 110.

Therefore, the original cavity 118a of FIG. 4A may be expanded under a high temperature environment, such that an expanded cavity 118b having a size larger than that of the electronic component to be embedded may be formed.

A margin space for easiness of subsequent embedding of the electronic component may be secured by forming the expanded cavity 118b as described above.

However, the expanding of the cavity is not limited thereto, but a temperature, a time, and the like, may be appropriately controlled in consideration of the coefficient of thermal expansion (CTE) of the material of the core layer 112 constituting the core board 110.

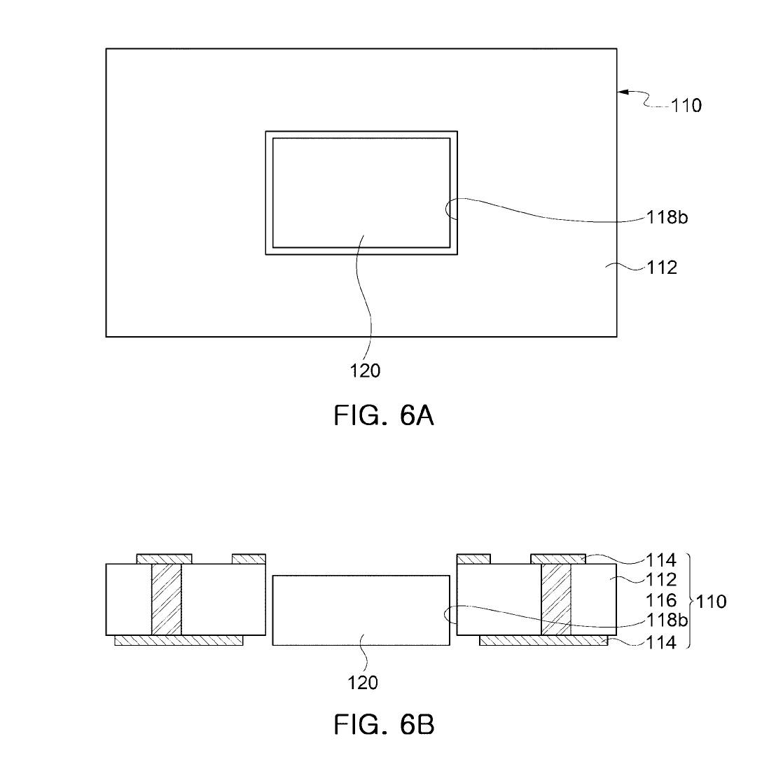

Next, as illustrated in FIGS. 3, 6A, and 6B, the electronic component 120 may be embedded in the expanded cavity 118b (S330).

The embedding of the electronic component 120 (S330) may be performed by positioning the electronic component 120 on the expanded cavity 118b of the core board 110 after positioning the core board 110 on a substrate (not illustrated).

Therefore, in a case in which an inner layer circuit pattern 114 is formed on a lower surface of the core layer 112, a lower surface of the electronic component 120 may be positioned on the same plane as a lower surface of the inner layer circuit pattern 114 formed on the lower surface of the core layer 112.

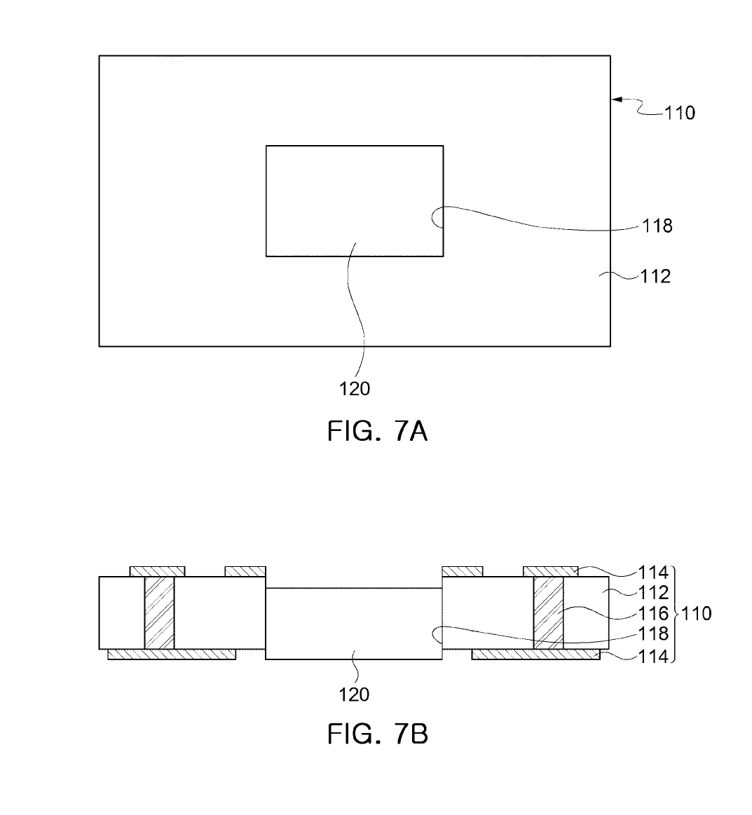

Then, referring to FIGS. 3, 7A, and 7B, the expanded cavity 118b of FIG. 6A is contracted by a second external stimulus so as to have a size equal to that of the embedded electronic component 120 (S340).

For example, the second external stimulus may be some physical and/or chemical stimulation applied from the outside to the core board 110 embedded with the electronic component 120. For example, the second external stimulus may be a temperature.

In detail, the second external stimulus may be cooling, which is one of methods capable of lowering a temperature of the core board 110.

The second external stimulus may be a temperature lower than the first external stimulus required for expansion of the cavity, and this temperature may be lower than the first external stimulus by at least 80° C.

As an example, the contracting of the cavity (S340) may be performed by maintaining the temperature of the core board 110 including the expanded cavity 118b of FIG. 6A at room temperature, a temperature of about 20 to 25° C., for a predetermined time.

In a case in which a temperature range of the second external stimulation is outside of the above-mentioned range, contract of the cavity to the same size as that of the electronic component 120 may not be sufficiently performed.

However, the contracting of the cavity is not limited thereto, and temperature, time, or the like, at the time of cooling may be appropriately controlled in consideration of the coefficient of thermal expansion (CTE) of the material of the core layer 112 constituting the core board 110.

Therefore, the expanded cavity 118b of FIG. 6A may be contracted by a cooling treatment, such that a final cavity 118 having the same size as that of the embedded electronic component 120 may be obtained.

In this case, side surfaces of the electronic component 120 and the cavity 118 may contact each other to thereby be fitted to each other without an aid of a separately prepared filler, such that an interface between the side surfaces of the electronic component 120 and the cavity 118 may be formed as a contact surface.

As a result, since an existing resin filler having a large CTE is not included between the side surfaces of the electronic component 120 and the cavity 118, a discontinuous CTE gap in the horizontal direction of the printed circuit board 100 may be removed, such that an occurrence amount of warpage due to a difference in CTE in the horizontal direction may be decreased.

Meanwhile, in order to allow the cavity to be expanded and contracted by the external stimuli such as temperature, thermal expansion characteristics of the core layer 112 depending on temperature may be used by continuously performing the expanding of the cavity (S320), the embedding of the electronic component (S330), and the contracting of the cavity (S340).

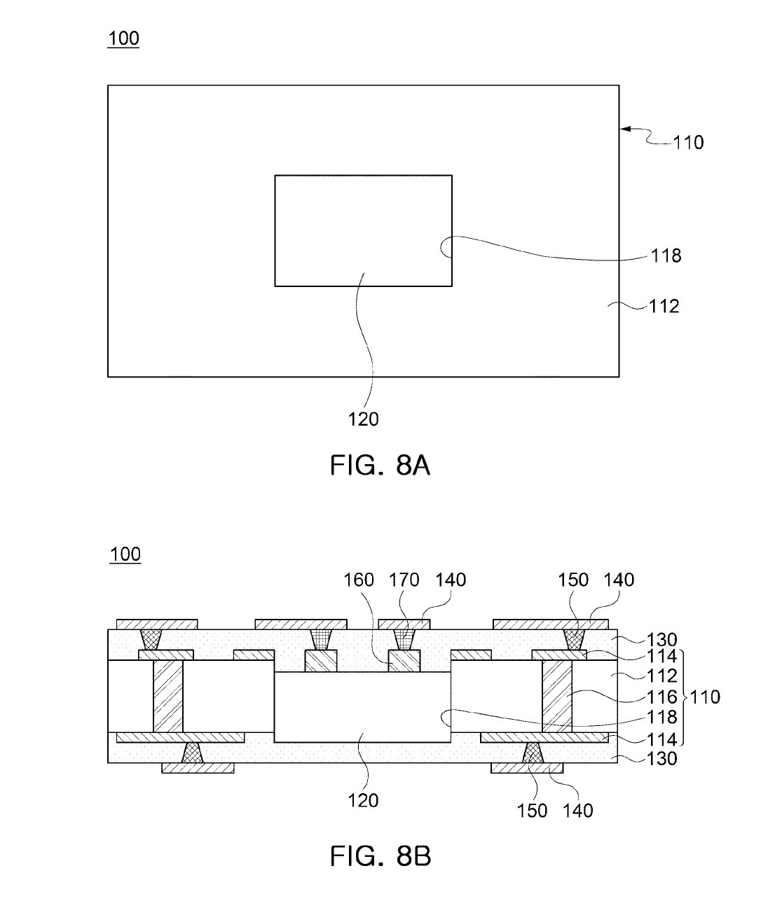

Thereafter, as illustrated in FIGS. 3, 8A and 8B, insulating layers 130 may be simultaneously stacked on opposite surfaces of the core board 110 embedded with the electronic component 120 (S350), thereby completing the printed circuit board 100.

The insulating layers 130 may be simultaneously stacked by preparing two sheets of prepreg (PPG) in which an outer layer circuit pattern 140, vias 150 and 170, a contact pad 160, and the like, are provided, positioning one sheet of prepreg (PPG) on each of the upper and lower surfaces of the core board 110 embedded with the electronic component 120, and performing the pressing and heating thereon.

In a case in which a cavity is larger than an electronic component, since there is a need to fill a gap generated in the cavity after embedding the electronic component, generally, upper and lower insulating layers are formed on a core layer by a sequential stacking method. Since amounts of a resin used in the upper and lower insulating layers, thicknesses of the upper and lower insulating layers, or the like, are different from each other due to the gap generated in the cavity, it is difficult to adjust degrees of curing, curing shrinkage, and the like, of the upper and lower insulating layers to the same level, such that the sequential stacking method as described above may become a cause of warpage.

In a case of using a simultaneous stacking method according to the present embodiment, an insulating material may be stacked so as to have a small thickness deviation between the upper and lower insulating layers, such that degrees of curing and curing shrinkages of the upper and lower insulating layers 130 may be almost the same as each other. Therefore, the occurrence amount of warpage due to the differences in degrees of curing and curing shrinkage in the perpendicular direction of the board may be decreased.

Further, in this example, at the time of stacking the insulating layers 130, there is no need to fill a gap of the cavity 118, and adjustment of an amount of a resin for filling the gap of the cavity may be omitted. Thus, an excessive decrease of a height of one side of the upper and lower insulating layers during the stacking, or the like, may be prevented, such that process reliability may be improved.

Meanwhile, since the outer layer circuit patterns 140, the vias 150 and 170, the contact pad 160, and the like, may be formed in the insulating layers 130 by a method generally known in the art, a detailed description thereof will be omitted.

As described above, according to the present example, the printed circuit board capable of decreasing warpage due to a structure in which the insulating layers are simultaneously formed on opposite surfaces of the core board in addition to a structure in which the Discontinuous CTE gap does not exist in the horizontal direction of the board may be manufactured by newly introducing the expanding of the cavity and the contracting of the cavity.

As set forth above, according to embodiments in the present disclosure, in the printed circuit board, since the side surfaces of the electronic component and the cavity may contact each other, the Discontinuous CTE gap does not exist in the horizontal direction, and the insulating layers are simultaneously formed in the perpendicular direction, such that the occurrence amount of warpage due to the difference in the CTE in the horizontal direction and the difference in curing degree and curing shrinkage in the perpendicular direction may be decreased.

Further, the printed circuit board capable of decreasing warpage due to the structure in which there is no filler between the cavity and electronic component and the structure in which the insulating layers may be simultaneously formed may be manufactured by newly introducing the expanding of the cavity and the contracting of the cavity.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board comprising:
a core board having a cavity that penetrates through a region of a core layer;
an electronic component embedded in the cavity, side surfaces of the cavity contacting the electronic component; and
insulating layers disposed on opposite surfaces of the core board.

2. The printed circuit board of claim 1, wherein the insulating layers on opposite surfaces of the core board has degrees of curing and curing shrinkages that are substantially equal to each other.

3. The printed circuit board of claim 1, wherein the core board further comprises inner layer circuit patterns contacting at least one of upper and lower surfaces of the core layer.

4. The printed circuit board of claim 3, wherein a lower surface of the electronic component is positioned on the same plane as lower surfaces of the inner layer circuit patterns formed on the lower surface of the core layer.

5. The printed circuit board of claim 3, wherein the core board further comprises a first via formed in the core layer and electrically connecting the inner layer circuit patterns formed on the upper and lower surfaces of the core layer to each other.

6. The printed circuit board of claim 3, further comprising:
outer layer circuit patterns formed on at least one surface of the insulating layer; and
second and third vias provided in the insulating layer and electrically connecting the outer layer circuit patterns to the inner layer circuit patterns or the electronic component, respectively.

7. The printed circuit board of claim 3, further comprising a contact pad interposed between the electronic component and the third via in the insulating layer.

8. A method of manufacturing a printed circuit board, comprising:
forming a cavity to penetrate through a region of a core layer of a core board such that the cavity has a size equal to or smaller than a size of an electronic component to be embedded in the cavity;
expanding the cavity by a first external stimulus to a size larger than a size of the electronic component;
embedding the electronic component in the expanded cavity;
contracting the cavity in which the electronic component is embedded by a second external stimulus such that side surfaces of the cavity contact the electronic component; and
forming insulating layers on opposite surfaces of the core board embedded with the electronic component.

9. The method of claim 8, wherein at least one of the first and second external stimuli is a temperature.

10. The method of claim 9, wherein the second external stimulus has a temperature lower than a temperature of the first external stimulus.

11. The method of claim 10, wherein the first external stimulus is heating, and the second external stimulus is cooling.

12. The method of claim 8, wherein at the time of contracting the cavity of the core board embedded with the electronic component, the electronic component is inserted into the cavity.
